(19) United States
(12) Patent Application Publication
(10) Pub. No.: US 2025/0169264 A1
(43) Pub. Date: May 22, 2025

(54) STRETCHABLE OTFT ELEMENT, SKIN ATTACHABLE TEMPERATURE SENSOR AND THE MANUFACTURING METHOD THEREOF

(71) Applicant: UNIVERSITY-INDUSTRY COOPERATION GROUP OF KYUNG HEE UNIVERSITY, Yongin-si (KR)

(72) Inventors: Jin Young OH, Anyang-si (KR); Min Woo JEONG, Gwangmyeong-si (KR); Jun Su KIM, Yongin-si (KR)

(73) Assignee: UNIVERSITY-INDUSTRY COOPERATION GROUP OF KYUNG HEE UNIVERSITY, Yongin-si (KR)

(21) Appl. No.: 18/939,784

(22) Filed: Nov. 7, 2024

(30) Foreign Application Priority Data
Nov. 21, 2023 (KR) 10-2023-0162616

(51) Int. Cl. H10K 10/46; G01K 7/01; H10K 71/12; H10K 71/16; H10K 71/60; H10K 85/10; H10K 85/20; H10K 85/60

(52) U.S. Cl. CPC H10K 10/466; H10K 71/12; H10K 71/164; H10K 71/611; H10K 85/113; H10K 85/20; H10K 85/6576; G01K 7/015

(57) ABSTRACT

Provided is a stretchable organic thin film field effect transistor (OTFT) element with high sensitivity and low power characteristic as a temperature sensor element that resolved instability caused by charge trap density induced as strain or heat in a sub-threshold region.

### CROSS-REFERENCE TO RELATED APPLICATION(S)

This application claims priority from and the benefit of Korean Patent Application No. 10-2023-0162616 filed on Nov. 21, 2023, which is hereby incorporated by reference in its entirety.

### BACKGROUND

### 1. Field

Example embodiments relate to a temperature sensor, and more particularly, to a stretchable temperature sensing active matrix organic thin film field effect transistor (OTFT) (hereinafter, referred to as OTFT element) and a skin attachable temperature sensor manufactured based on the OTFT and a manufacturing method thereof.

### 2. Related Art

Many diseases are identified by a change in body temperature and constantly monitoring this makes it possible to acquire information on a current health status and, at the same time, to prevent infectious diseases. With the recent spread of infectious diseases such as influenza and COVID-19, real-time body temperature measurement has become an essential prerequisite. To meet this need, a skin-like temperature sensor is attracting attention since the temperature sensor's direct integration with the human body or attachment to the skin is robust against body movement and does not cause foreign body sensation.

An organic thin film field effect transistor (OTFT), which is based on inherent mechanical softness and high temperature dependence in hopping transport of charge carriers in an organic semiconductor, has excellent cross-sensitivity compared to the conventional 2-terminal temperature sensor such as thermistor and capacitor. For this reason, the OTFT is a promising candidate of a temperature sensor such as electronic skin through an active matrix array. Currently, due to the rapid development of intrinsically stretchable organic semiconductor materials, particularly, organic polymers, the potential of the OTFT is attracting attention as a skin-like sensor.

A stretchable wearable sensor ultimately requires high response to a physiological signal with low power consumption and skin compliance. However, power-response tradeoff and detection instability due to strain remain major challenges for an electronic skin (e-skin) sensor. Therefore, for the stretchable OTFT to be applied as a temperature sensor attached to the skin, the stretchable OTFT needs to overcome low temperature sensitivity and electrical instability when deformed. Also, considering the electrical capacity of a limited charging battery, an operating voltage needs to be lowered to reduce power consumption.

Accordingly, a sub-threshold scheme with an operating voltage close almost to zero voltage and highest transconductance efficiency (gm/I_{D}) is proposed to achieve high signal gain and low power consumption in electric field transistor-based sensor application. Here, I_{D} denotes drain current.

However, instability caused by charge trap density induced as strain or heat in a sub-threshold region is presented as limitation for application of OTFT as a high-sensitivity and low-power stretchable sensor.

### SUMMARY

Example embodiments are to provide a stretchable organic thin film field effect transistor (OTFT) element with high sensitivity and low power characteristic as a temperature sensor element that resolves instability caused by charge trap density induced as strain or heat in a sub-threshold region.

Example embodiments are to provide a skin attachable temperature sensor manufactured by applying a stretchable material to implement a skin-like active matrix temperature sensor array.

Example embodiments are to provide a skin attachable temperature sensor manufacturing method by applying a stretchable material to implement a skin-like active matrix temperature sensor array.

Example embodiments are to provide a skin attachable temperature sensor with high sensitivity and low power characteristic based on a stretchable organic transistor that detects temperature in a sub-threshold region with high transconductance.

According to an example embodiment, there is provided a stretchable organic thin film field effect transistor (OTFT) element including a gate electrode; a dielectric layer stacked with elastomer on the gate electrode; an active layer stacked on the dielectric layer; and a source electrode and a drain electrode formed to be spaced part from each other on the active layer, wherein the active layer is formed as an elastomer matrix organic semiconductor nanofiber blend film in which organic semiconductor nanofiber is mixed within an elastomer matrix.

According to an example embodiment, there is provided a skin attachable temperature sensor including a substrate formed of elastomer; a first electrode layer formed on the substrate by including at least one gate electrode; a dielectric layer stacked with the elastomer on the substrate and the first electrode layer; an active layer stacked on the dielectric layer; a second electrode layer stacked on the active layer by including at least one source electrode and drain electrode; and a capsule layer configured to seal the top of the second electrode layer, wherein the active layer is formed as an elastomer matrix organic semiconductor nanofiber blend film in which organic semiconductor nanofiber is mixed within an elastomer matrix.

According to an example embodiment, there is provided a method of manufacturing a skin attachable temperature sensor, the method including a substrate, dielectric layer, and active layer manufacturing operation of simultaneously or sequentially manufacturing a substrate, a dielectric layer, and an active layer on each of separated wafers or glass substrates; a first electrode layer forming operation of forming stretchable at least one gate electrode on the substrate through thermal evaporation under vacuum using a patterning mask; a second electrode layer forming operation of forming at least one source electrode and drain electrode on the active layer; and a dielectric layer and active layer transferring operation of transferring the dielectric layer on the substrate on which the first electrode layer is formed and transferring the active layer on the dielectric layer such that the second electrode layer is present on the top, wherein, in the substrate, dielectric layer, and active layer manufacturing operation, the active layer is manufactured by mixing organic semiconductor nanofiber of Formula 1 below and elastomer of Formula 2 below in a solvent that contains a material of Formula 3 below.

Further areas of applicability will become apparent from the description provided herein. The description and specific examples in this summary are intended for purposes of illustration only and are not intended to limit the scope of the present disclosure.

### BRIEF DESCRIPTION OF THE FIGURES

Embodiments will be described in more detail with regard to the figures, wherein like reference numerals refer to like parts throughout the various figures unless otherwise specified, and wherein:

FIG. 1 is a perspective view of a stretchable temperature sensing active matrix organic thin film field effect transistor (OTFT) element 100 according to an example embodiment;

FIG. 2 illustrates a stacked structure of a skin attachable temperature sensor 1 having an OTFT array 200 that is an array of OTFT elements 100 shown in FIG. 1 according to an example embodiment;

FIG. 3, (a) and (b), are optical microscopy (OM) photos representing the OTFT element 100 and a temperature sensor 1, respectively;

FIG. 4 is a graph showing a change in drain current in a turn-on region and a sub-threshold region of a transfer curve according to a change in temperature;

FIG. 5 is a flowchart illustrating a skin attachable temperature sensor manufacturing method according to an example embodiment;

FIG. 6, (a) and (b), are atomic force microscope (AFM) photos of a stretchable semiconductor to evaluate a fine phase separation structure;

FIG. 7, (a) and (b), are graphs showing a change in a transfer curve and an output curve of the stretchable temperature sensing active matrix OTFT element 100 according to a drain voltage (V_{D});

FIG. 8 is a graph showing a change in a sub-threshold slope and charge trap density according to a drain voltage;

FIG. 9 is a graph showing a change in electrical performance according to a temperature of a single stretchable OTFT element 100 in a sub-threshold region;

FIG. 10, (a), (b), and (c), are graphs showing results of evaluating electrical performance and characteristic according to a change in temperature of a single stretchable OTFT element 100 in a saturation region;

FIG. 11 is a graph showing results of evaluating temperature sensitivity according to a gate voltage of a single stretchable OTFT element 100;

FIG. 12 is a comparative graph of activation energy of a single stretchable OTFT element 100 in a saturation region and a sub-threshold region;

FIG. 13 is a graph showing results of evaluating NS-current and Vₜₕ change according to temperature;

FIG. 14 is a graph showing a change in crystallinity according to stretching of a green light emitting polymer semiconductor;

FIG. 15 is a graph showing results of evaluating a change in dielectric property according to a change in temperature;

FIG. 16, (a) and (b), show results of evaluating a change in surface morphology of a semiconductor included in an active layer 60 according to a change in temperature;

FIG. 17 is a graph showing results of evaluating a change in UV-vis absorption spectrum of a semiconductor film according to a change in temperature;

FIG. 18 is a graph showing results of evaluating a change in contact resistance according to a change in temperature;

FIG. 19 is a graph showing results of evaluating a change in a transfer mode of the OTFT element 100 according to a change in temperature;

FIG. 20, (a), (b), and (c), are graphs showing results of evaluating temperature sensitivity of a semiconductor film in a tensile strain environment in a channel horizontal direction;

FIG. 21, (a), (b), and (c), are graphs showing results of evaluating temperature sensitivity of a semiconductor film in a tensile strain environment in a channel vertical direction;

FIG. 22, (a) and (b), are graphs showing results of evaluating electrical property of 5×5 OTFT array 200;

FIG. 23, (a) and (b), are graphs showing a transfer curve and an output curve in a sub-threshold region of the OTFT array 200 according to a change in temperature, respectively;

FIG. 24, (a) and (b), are graphs showing results of evaluating temperature sensitivity according to tensile strain of the OTFT array 200;

FIG. 25 is a graph showing results of evaluating a change in drain current (I_{D}) according to real-time temperature in a range similar to body temperature of the temperature sensor 1;

FIG. 26 is a graph showing comparative evaluation results of stretchability and temperature sensitivity according to a key design factor in a temperature sensor using the OTFT array 200;

FIG. 27 is a graph showing comparative evaluation results of power consumption among flexible and stretchable transistor temperature sensor elements;

FIG. 28 is a graph showing comparative evaluation results of current response speed according to a change in reverse and forward temperature;

FIG. 29 is a graph showing results of evaluating current stability in various strain environments;

FIG. 30, (a), (b), and (c), are graphs showing NS-current and deformed 3D mapping using a cold or hot metal ball; and

FIG. 31, (a), (b), and (c), are graphs showing results of evaluating temperature sensing accuracy using NS-current changed due to a cold or hot metal ball.

### DETAILED DESCRIPTION

The following structural or functional descriptions of example embodiments according to the concept of the present invention described herein are merely intended for the purpose of describing the example embodiments according to the concept of the present invention and the example embodiments according to the concept of the present invention may be implemented in various forms and are not construed as limited to the example embodiments described herein.

Various modifications and various forms may be made to the example embodiments according to the concept of the present invention and thus, the example embodiments are illustrated in the drawings and is described in detail through the present specification. However, it should be understood that the example embodiments according to the concept of the present invention are not construed as limited to specific implementations and should be understood to include all changes, equivalents, and replacements within the idea and the technical scope of the present invention.

Although terms of “first,” “second,” and the like are used to explain various components, the components are not limited to such terms. These terms are used only to distinguish one component from another component. For example, a first component may be referred to as a second component, or similarly, the second component may be referred to as the first component without departing from the scope according to the concept of the present invention.

When it is mentioned that one component is “connected” or “accessed” to another component, it may be understood that the one component is directly connected or accessed to another component or that still other component is interposed between the two components. In addition, when it is described that one component is “directly connected” or “directly accessed” to another component, it should be understood that still other component is absent therebetween. Likewise, expressions, for example, “between” and “immediately between” and “immediately adjacent to” may also be construed as described in the foregoing.

The terminology used herein is for the purpose of describing particular example embodiments only and is not to be limiting of the present invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, stages, operations, elements, components or combinations thereof, but do not preclude the presence or addition of one or more other features, integers, stages, operations, elements, components, or combinations thereof.

Unless otherwise defined herein, all terms used herein including technical or scientific terms have the same meanings as those generally understood by one of ordinary skill in the art. Terms defined in dictionaries generally used should be construed to have meanings matching contextual meanings in the related art and are not to be construed as an ideal or excessively formal meaning unless otherwise defined herein.

Hereinafter, example embodiments will be described in detail with reference to the accompanying drawings. However, the scope of the claims is not limited to or restricted by the example embodiments. Like reference numerals presented in the respective drawings refer to like components throughout.

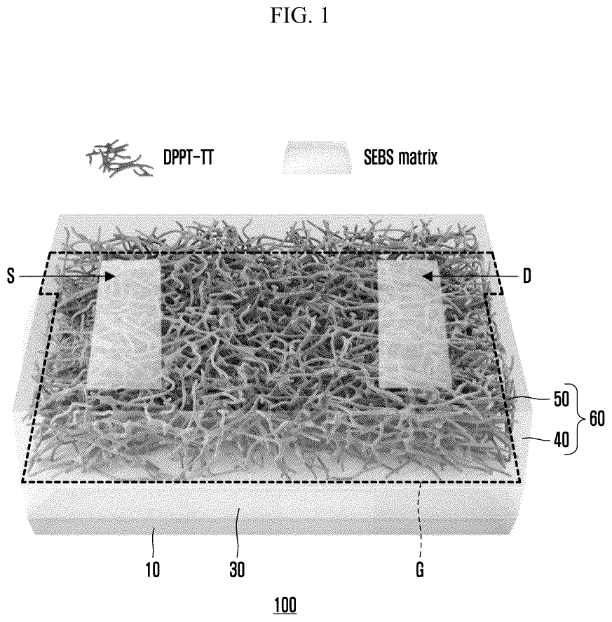

FIG. 1 is a perspective view of a stretchable temperature sensing active matrix OTFT element 100 according to an example embodiment.

Referring to FIG. 1, the OTFT element 100 may be configured to have stretchability by including a gate electrode (G), a dielectric layer 30 stacked with elastomer on the gate electrode (G), an active layer 60 stacked on the dielectric layer 30, and a source electrode (S) and a drain electrode (D) formed on the active layer 60. A region of the active layer 60 between the source electrode (S) and the drain electrode (D) may be an active region that forms a channel to flow current between the source electrode (S) and the drain electrode (D).

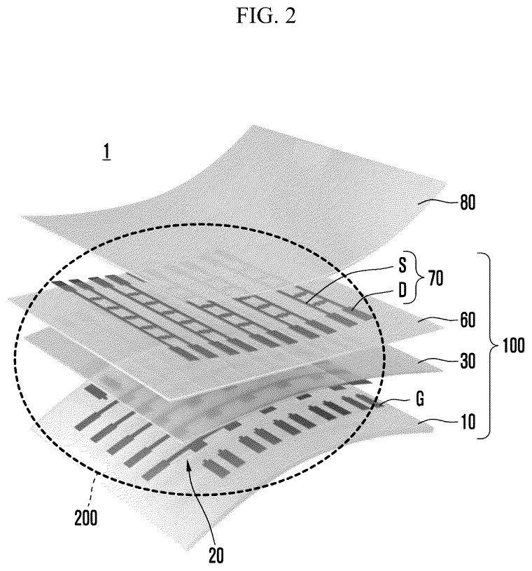

FIG. 2 illustrates a stacked structure of a skin attachable temperature sensor 1 (hereinafter, temperature sensor 1) having an OTFT array 200 that is an array of OTFT elements 100 shown in FIG. 1 according to an example embodiment.

Referring to FIG. 2, the temperature sensor 1 may include a substrate 10 formed of elastomer, a first electrode layer 20 formed on the substrate 10 by including at least one gate electrode (G), the dielectric layer 30 stacked with the elastomer on the substrate 10 and the first electrode layer 20, the active layer 60 stacked on the dielectric layer 30, a second electrode layer 70 stacked on the active layer 60 by including at least one source electrode (S) and drain electrode (D), and a capsule layer 80 configured to seal the top of the second electrode layer 70.

Referring to FIGS. 1 and 2, the active layer 60 may be formed as an elastomer matrix organic semiconductor nanofiber blend film in which organic semiconductor nanofiber 50 is mixed within the elastomer matrix.

An organic semiconductor that forms the organic semiconductor nanofiber 50 may be DPPT-TT that is [poly-[2, 5-bis 2-octyldodecyl)-3, 6-di(thiophen-2-yl) pyrrolo [3, 4-c]pyrrole-1,4 2H, 5H)-dionel-alt-thieno [3, 2-b]thiophene] represented by Formula 1 below.

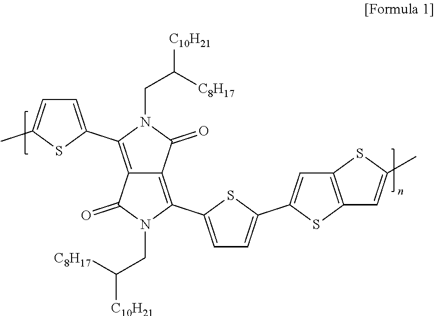

The above DPPT-TT may have an average molecular weight of 100,000 g/mol or more.

The elastomer may be styrene-ethylene-butylene-styrene (SEBS) organic elastomer that is represented by Formula 2 below.

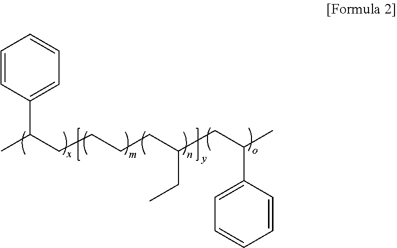

In the SEBS of Formula 2 above, (x+o) to (m+n) may have a composition ratio of 18:82 to 20:80.

The elastomer matrix organic semiconductor nanofiber blend film that forms the active layer 60 may be a DPPT-TT nanofiber SEBS blend film (DPPT-TT:SEBS blend film) in which a film of the organic semiconductor nanofiber 50 is formed within a SEBS matrix 40 due to nano confinement effect.

The DPPT-TT:SEBS blend film may be manufactured by dissolving DPPT-TT represented by Formula 1 above and SEBS represented by Formula 2 above in a material of Formula 3 below at a concentration of 0.6 to 0.8% by weight at a weight ratio of 1 to 3:7 to 9.

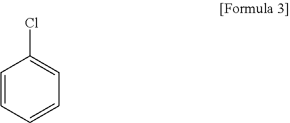

The substrate 10 may be manufactured by mixing the material of Formula 2 above with a material of Formula 4 below at a concentration of 90 to 110 mg/mL and then performing spin coating on a rigid substrate.

The dielectric layer 30 may be a SEBS matrix manufactured by mixing the material of Formula 2 above with the material of Formula 4 below at a concentration of 50 to 70 mg/mL and then performing spin coating on the rigid substrate.

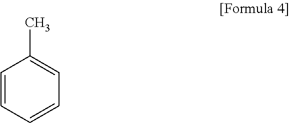

The first electrode layer 20 and the second electrode layer 70 may be formed on the substrate 10 and the active layer 60, respectively, each formed on the rigid substrate such as a glass substrate, by a transfer printing method that uses thermally evaporated Ag metallization.

Then, the stretchable temperature sensor 1 may be manufactured by transferring the substrate 10 on the rigid substrate to the active layer 60 such that the first electrode layer 20 is located between the substrate 10 and the active layer 60 and such that the second electrode layer 70 is located on the active layer 60.

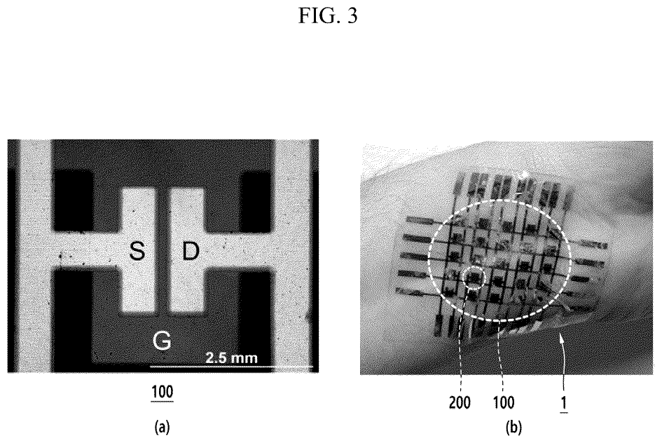

FIG. 3, (a) and (b), are optical microscopy (OM) photos representing the OTFT element 100 and the temperature sensor 1, respectively.

Referring to (a) of FIG. 3, the OTFT element 100 may include the active layer 60 formed as the DPPT-TT:SEBS blend film present on the gate electrode (G) and the source electrode (S) and the drain electrode (D) formed on the active layer 60.

Referring to (b) of FIG. 3, the temperature sensor 1 may be manufactured to be attachable to the skin of a person (e.g., the inner skin of the wrist in FIG. 3) by including the OTFT array 200 that includes the OTFT elements 100 formed by the gate electrodes (G) and the source electrodes (S) and the drain electrodes (D) respectively formed on the substrate 10 and the active layer 60 of FIGS. 1 and 2.

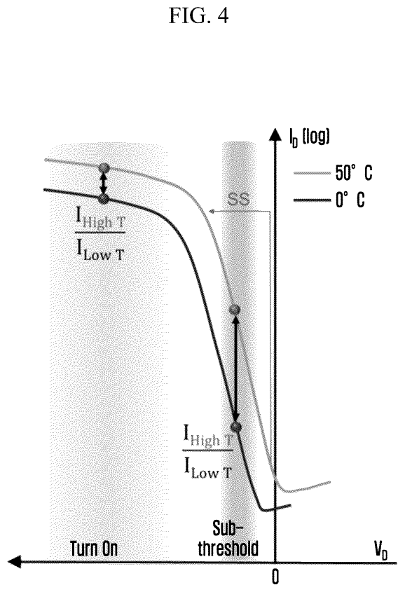

FIG. 4 is a graph showing a change in drain current according to drain voltage (V_{D}) in a turn-on region and a sub-threshold region of a transfer curve according to a change in temperature.

Referring to FIG. 4, a sub-threshold slope of a transfer curve of the OTFT element 100 becomes steeper. This indicates that transconductance efficiency increases at a low drain voltage (V_{D}), resulting in high response to thermal stimulation with low power consumption.

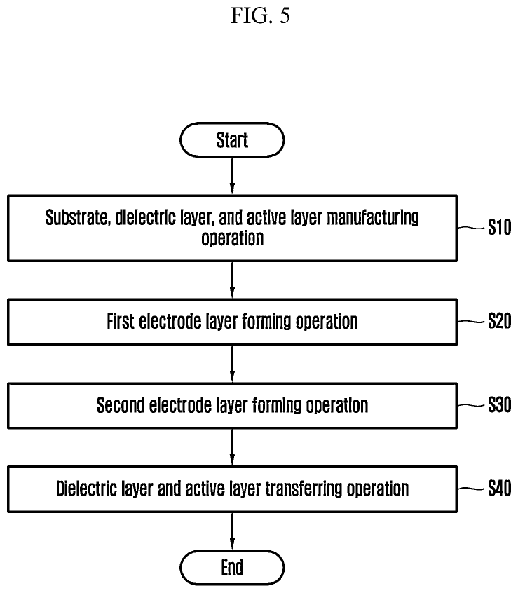

FIG. 5 is a flowchart illustrating a skin attachable temperature sensor manufacturing method according to an example embodiment.

Referring to FIG. 5, the skin attachable temperature sensor manufacturing method of an example embodiment may include substrate, dielectric layer, and active layer manufacturing operation S10, first electrode layer forming operation S20, second electrode layer forming operation S30, and dielectric layer and active layer transferring operation S40.

In substrate, dielectric layer and active layer manufacturing operation S10, manufacturing of the substrate 10, the dielectric layer 30, and the active layer 60 may be simultaneously or sequentially performed on each separated wafer or glass substrate.

In substrate, dielectric layer and active layer manufacturing operation S10, the substrate 10 may be manufactured by mixing the material of Formula 2 above with the material of Formula 4 above at a concentration of 90 to 110 mg/mL and then performing spin coating on a rigid substrate.

When the material of Formula 2 above is mixed with the material of Formula 4 above at a concentration of less than 90 mg/mL or greater than 110 mg/mL, stretchability of the substrate 10 may be reduced.

The concentration of solution for manufacturing the substrate 10 determines a thickness of the substrate 10. When the concentration of solution for manufacturing the substrate 10 is less than 90 mg/ml, the substrate 10 becomes too thinner and difficult to control, which may decrease processing property. When the concentration of solution for manufacturing the substrate 10 exceeds 110 mg/ml, the substrate 10 becomes too thicker and the tensile strength of the substrate 10 itself increases and, at the same time, conformable contact may be difficult when attached to other places such as the skin.

In substrate, dielectric layer, and active layer manufacturing operation S10, manufacturing of the dielectric layer 30 relates to forming the SEBS matrix as the dielectric layer 30 by mixing the material of Formula 2 above with the material of Formula 4 above at a concentration of 50 to 70 mg/mL and then performing spin coating on the rigid substrate.

If the material of Formula 2 above is mixed with the material of Formula 4 above at a concentration of less than 50 mg/mL or greater than 70 mg/mL, stretchability of the dielectric layer 30 may decrease.

In the case of the dielectric layer 30, the insulating property may significantly vary depending on the thickness. Therefore, if the material of Formula 2 above is mixed at a concentration of less than 50 mg/ml, the insulating property may significantly decrease. If the material of Formula 2 above exceeds 70 mg/ml, on-current of the element may decrease.

In substrate, dielectric layer, and active layer manufacturing operation S10, manufacturing of the active layer 60 may relate to manufacturing a DPPT-TT:SEBS blend film in which an organic semiconductor nanofiber is formed within the SEBS matrix by dissolving DPPT-TT represented by Formula 1 above and SEBS represented by Formula 2 above with the material of Formula 3 above at a concentration of 0.6 to 0.8% by weight at a weight ratio of 1 to 3:7 to 9 for the total weight on the rigid substrate and generating a filtration solution and by spin-coating and then annealing the filtration solution on a wafer on which an oxide film is formed.

If the weight ratio of the material of Formula 1 above to Formula 2 above is less than 1:9, the semiconductor property of the active layer 60 may decrease. If the weight ratio of the material of Formula 1 above to Formula 2 above exceeds 3:7, the semiconductor property and stretchability of the active layer 60 may decrease.

In the case of a semiconductor layer, a mixture ratio is very related to stretchability. The mixture ratio of the semiconductor layer represents stretchability and film morphology or electrical property. If the weight ratio of the mixed material of Formula 1 and Formula 2 is less than 1:9, the stretchability may significantly increase, but electrical performance may significantly decrease. On the contrary, if the weight ratio exceeds 3:7, the electrical performance may increase, but the stretchability may decrease and film morphology may become non-uniform.

First electrode layer forming operation S20 may relate to forming the stretchable (Ag 50 nm) gate electrode (G) on the stretchable substrate 10 through thermal evaporation under high vacuum (5.0×10-6 torr or less) using a patterning mask.

Second electrode layer forming operation S30 may relate to forming the stretchable (Ag 50 nm) source electrode (S) and drain electrode (D) through thermal evaporation using the patterning mask on the active layer 60 that is a stretchable semiconductor layer. In second electrode layer forming operation S30, at least one source electrode and drain electrode may be formed on the DPPT-TT:SEBS blend film.

Dielectric layer and active layer transferring operation S40 may relate to manufacturing the stretchable skin attachable temperature sensor 1 with the OTFT array 200 by transferring the dielectric layer 30 on the substrate 10 on which the gate electrode is formed and by transferring the active layer 60 on the dielectric layer 30.

Then, to protect the temperature sensor 1, the capsule layer 80 may be formed by depositing the SEBS matrix on the second electrode layer 70 and the active layer 60.

### Embodiment

### 1. Materials

Poly[2,5-(2-octyldodecyl)-3, 6-diketopyrrolopyrrole-alt-5, 5-(2, 5-di(thienyl) thieno[3, 2b]thiophen)](DPPT-TT) was purchased from Derthon. The molecular weight of polymer and polydispersity index (PDI) were Mn>33 k and PDI=3.0, respectively.

Styrene-ethylene-butylene-styrene (SEBS) elastomer was provided from AsahiKASEI. H1062 (18% styrene content) and H1052 (20% styrene content) were used for the film of the organic semiconductor nanofiber 50 as a semiconductor layer and mixed component of the elastomer substrate 10 and the dielectric layer 30, respectively. All materials were used as purchased.

### 2. Device Manufacturing—Rigid Substrate-Based OTFT

To manufacture a DPPT-TT:SEBS blend film that is a stretchable semiconductor film, the active layer 60, DPPT-TT and SEBS H1062 were dissolved in anhydrous chlorobenzene at a concertation of 0.7% by weight at a weight ratio of 2:8. Here, the dissolution may be performed at 120° C. for 2 to 4 hours.

To manufacture the DPPT-TT:SEBS blend film as a semiconductor film, the DPPT-TT:SEBS blend film, a stretchable semiconductor film, was manufactured by spin-coating a solution filtered using a 0.2 μm PTFE-D filter on an octadecyltrimethoxysilane (OTS) treated Si wafer at 1000 rpm for 1 minute using 300 nm SiO₂ and by annealing the same in an N₂ atmosphere glove box (H2O<0.01 ppm, O2<0.01 ppm) at 180° C. for 1 hour (active layer manufacturing operation in substrate, dielectric layer, and active layer manufacturing operation S10).

Finally, the rigid substrate-based organic thin film field effect transistor (OTFT) array 200 was manufactured by evaporating silver using a thermal evaporator (W: 1000 μm, L: 150 μm) and by forming the source electrode (S) and the drain electrode (D) (second electrode layer forming operation S30).

The stretchable dielectric layer 30 was prepared by spin-coating a SEBS H1052 solution (60 mg/mL in toluene) on the glass substrate on which an indium tin oxide (ITO) gate electrode (initial resistance 20Ω) was formed (dielectric layer manufacturing operation in substrate, dielectric layer, and active layer manufacturing operation S10).

Then, the elastomer matrix substrate 10 was transferred from the OTS-treated Si wafer to the SEBS/ITO glass substrate using a polydimethyl siloxane (PDMS) stamp.

### 3. Device Manufacturing—Stretchable Temperature Sensing Active Matrix OTFT Array 200

The substrate 10 for the OTFT array 200 was prepared by casting 10 mL of SEBS H1062 solution (100 mg/mL in toluene) on a glass slide. A thickness of the manufactured stretchable substrate 10 was about 0.05 mm (substrate manufacturing operation in substrate, dielectric layer, and active layer manufacturing operation S10).

Then, the stretchable Ag (50 nm) gate electrode (G) was manufactured on the stretchable substrate 10 through thermal deposition under high vacuum (5.0×10-6 torr or less) using a patterning mask (first electrode layer forming operation S20).

The spin-coated stretchable dielectric layer 30 (SEBS H1052 in toluene) and the active layer 60 including the film of the organic semiconductor nanofiber 50 within the SEBS matrix 40 for temperature sensing were sequentially transferred and printed from the OTS-Si wafer to the stretchable substrate 10 on which the Ag gate electrode (G) was prepared (dielectric layer and active layer transferring operation S40).

Then, the temperature sensor 1 of the embodiment with the OTFT array 200 was manufactured by forming the stretchable Ag (50 nm) source electrode (S) and drain electrode (D) on the active layer 60 that is the stretchable semiconductor layer, using the patterning mask.

### 4. Characterization—Temperature Depending Electrical Characterization of OTFT Array 200

Electrical characterization of the skin attachable temperature sensor 1 was performed using a Keithely 2400A source meter with customized LabVIEW (National Instruments) program.

To vary an operating temperature, a Seebeck effect probe station was connected to the Keithely 2400A source meter. In particular, all electrical measurement was performed at ambient conditions and had a stabilization time of 1 minute for temperature saturation of heated probe strain.

### 5. Characterization—Characterization of Film-Type Temperature Sensor 1

An atomic force microscopy (AFM) image was acquired using MULTIMOE-8J. All UV/visible/NIR absorption spectra were acquired using JASCO V-770. For UV-vis spectroscopic measurement, a sample of the temperature sensor 1 was prepared through spin-coating and annealing on the OTS wafer and then transferred onto the clean glass through the PDMS stamp. To investigate the effect of temperature on the formed aggregate, a single temperature sensor 1 was exposed to the environment of 0, 50, and 100° C. for 30 minutes each and then slowly returned to room temperature before each measurement.

### 6. Characterization—Real-Time Temperature Sensing of Temperature Sensor 1

Real-time electrical measurement of the temperature sensor 1 including the OTFT array 200 of sensing temperature was performed using Keithely 2400A.

To measure strain according to skin movement of a person, the temperature sensor 1 in which each of the source electrode (S), the drain electrode (D), and the gate electrode (G) was connected to the probe with gold wire was attached to the wrist of the person as shown in (b) of FIG. 3.

For 3D mapping of I_{D} at various temperatures that vary according to stretching conditions, the array was cooled in ice and heated and a vial containing pressured water was secured behind each edge of the array.

### 7. Character Evaluation

### <Microstructure Evaluation of Stretchable Semiconductor Film>

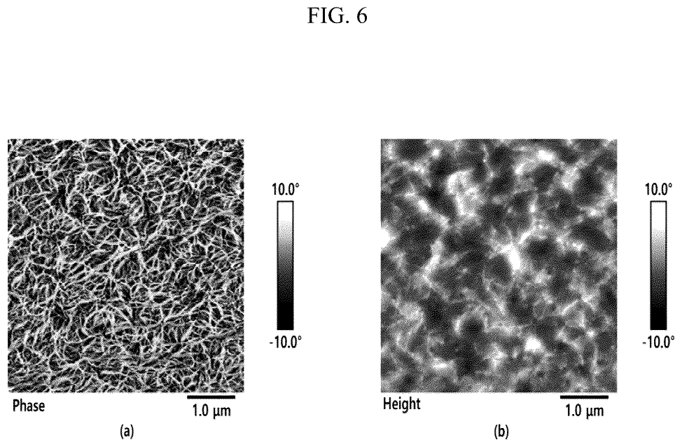

FIG. 6, (a) and (b), are atomic force microscope (AFM) photos of a stretchable semiconductor film to evaluate a fine phase separation structure.

FIG. 6 shows a fine phase separation structure occurring when a polymer semiconductor, which is an organic semiconductor, and elastomer are mixed.

(a) of FIG. 6 shows that the polymer semiconductor has a nanofiber structure when mixed with the elastomer and has a uniform distribution within the overall elastomer matrix.

(b) of FIG. 6 shows a height image, indicating that surface roughness of a manufactured stretchable semiconductor film is not high.

### <Evaluation of Change in Electrical Performance and Characteristic of Manufactured Stretchable Temperature Sensing Active Matrix OTFT Element 100 According to Drain Voltage>

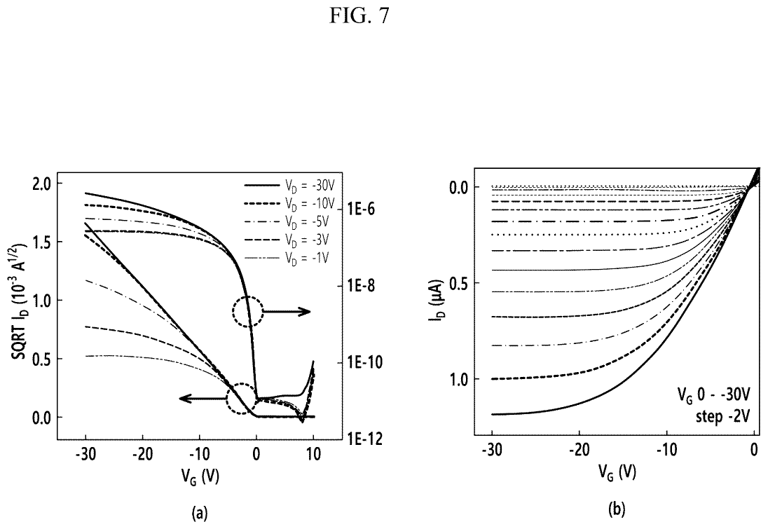

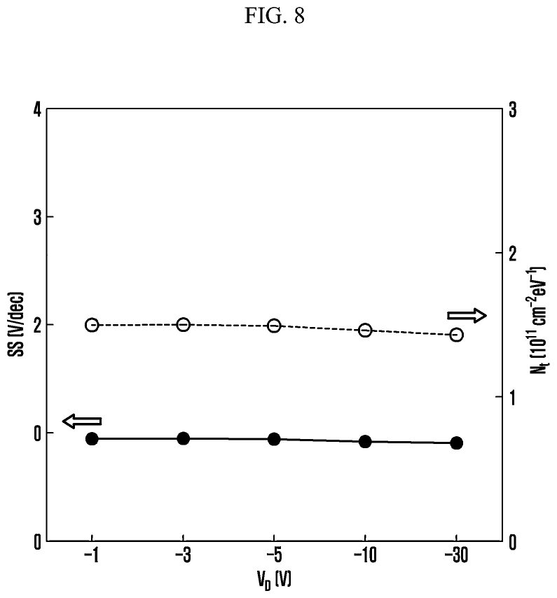

FIG. 7, (a) and (b), are graphs showing a change in a transfer curve and an output curve of the manufactured stretchable temperature sensing active matrix OTFT element 100 according to a drain voltage (V_{D}), and FIG. 8 is a graph showing a change in a sub-threshold slope and charge trap density according to a drain voltage (V_{D}).

FIGS. 7 and 8 show a change in electrical performance and characteristic of the OTFT element 100 according to the drain voltage (V_{D}) when the OTFT element 100 operates.

(a) of FIG. 7 shows a transfer characteristic of a single OTFT element 100 within the OTFT array 200 according to a change in temperature. A measurement temperature increased by 10° C. from 0° C. to 50° C.

(b) of FIG. 7 shows an output characteristic of a single OTFT element 100 within the 5×5 OTFT array 200.

(a) and (b) of FIG. 7 show the transfer curve and the output curve without double slope related to charge trap, respectively. Each transfer curve shows the tendency to be very consistent even with the change in the drain voltage (V_{D}). For the output curve, separation and linearity between initial curves were also well maintained.

Also, FIG. 8 shows the same sub-threshold slope (SS) with negligible threshold at gate voltage (V_{G}) between 0 and −2 V regardless of the drain voltage (V_{D}). This indicates a trap-free hole transport in a sub-threshold region. The charge trap density (Nt, 1.5×10¹¹/cm²·eV) calculated with a function of SS (0.8 V/dec) barely changed in the drain voltage (V_{D}) range between −30 V and −1 V. This indicates that the OTFT element 100 stably operates without drop in electrical performance, although the low drain voltage (V_{D}) and gate voltage (V_{G}) are used, compared to performance using high voltage.

### <Evaluation of Temperature Sensitivity Characteristic in Sub-Threshold Region>

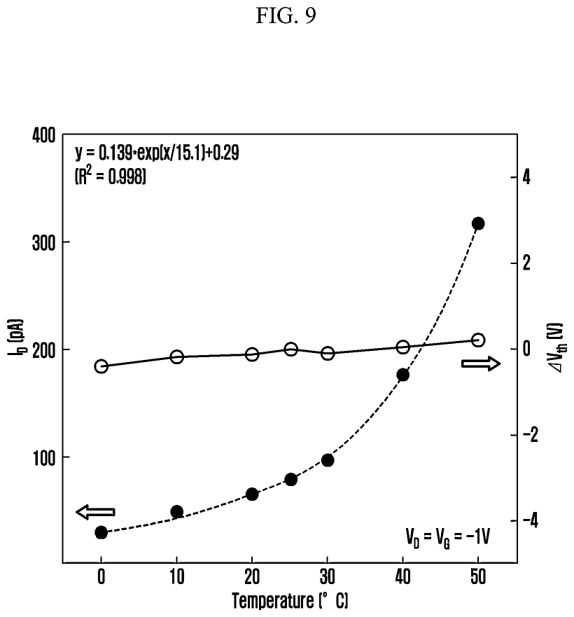

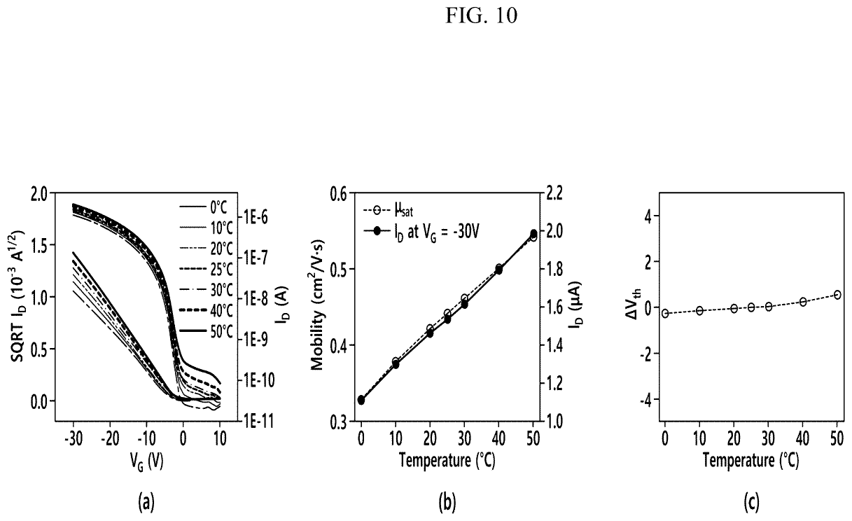

FIG. 9 is a graph showing a change in electrical performance according to a temperature of a single stretchable OTFT element 100 in a sub-threshold region, and FIG. 10, (a), (b), and (c), are graphs showing results of evaluating electrical performance and characteristic according to a change in temperature of a single stretchable OTFT element 100 in a saturation region.

FIG. 9 shows that ΔVₜₕ and current change in V_{D}, V_{G}=−1V region according to change in temperature of 0 to 50° C. The average reliability indicating ideality of the transfer curve underlying this data was 0.99. The closer the ideality of the transfer curve is to 1, the more ideal it is. The closer the ideality is to 0, the more non-ideal it is.

When the current exponentially increased from 29 pA to 317 pA, Vₜₕ was maintained at −3.3±0.5V and sub-threshold current occurred due to trap-free hopping transport. FIG. 10 shows that higher thermal activation energy than charge carrier transport in a saturation region is required.

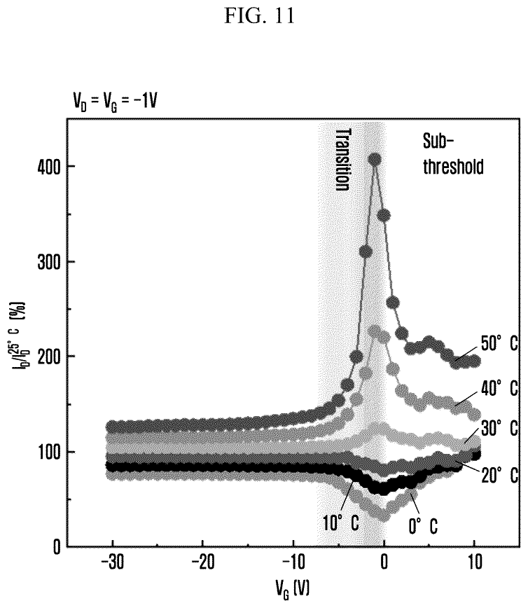

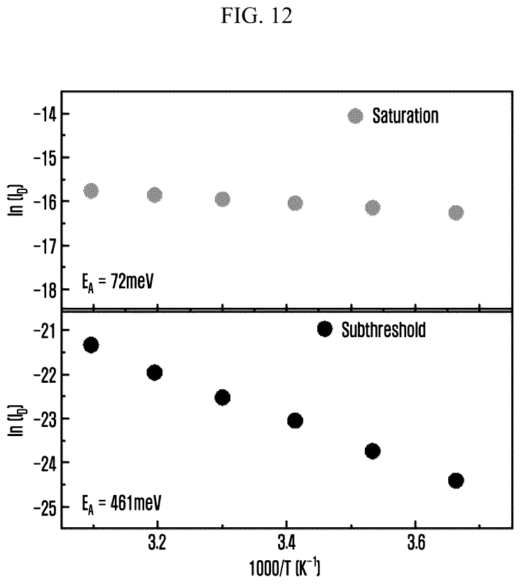

FIG. 11 is a graph showing results of evaluating temperature sensitivity according to a gate voltage of a single stretchable OTFT element 100, and FIG. 12 is a comparative graph of activation energy of a single stretchable OTFT element 100 in a saturation region and a sub-threshold region.

Referring to FIG. 11, normalized sub-threshold current (NS current) (I_{D}/I_{D}^{25° C.} and V_{D}=−1 V in V_{D}) is represented by a function of V_{G}. When evaluating sub-threshold current response to temperature, sensitivity according to temperature increased to 9.4%/° C. This is highest temperature sensitivity among previously reported polymer semiconductors. In addition, the response in the sub-threshold region was 7.7 times higher than that in the saturation region (1.2%/° C.). This reflects the higher activation energy for charge transport diffusion in the sub-threshold region compared to charge transport drift, as shown in FIG. 12.

### <Evaluation of NS-Current Long-Term Stability According to Temperature>

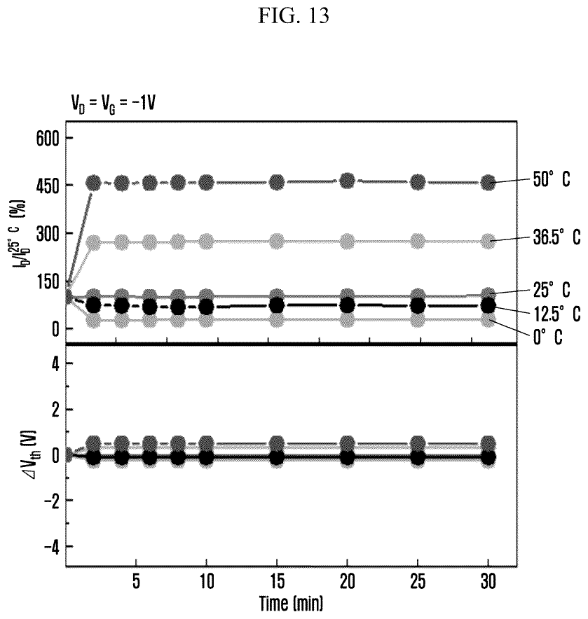

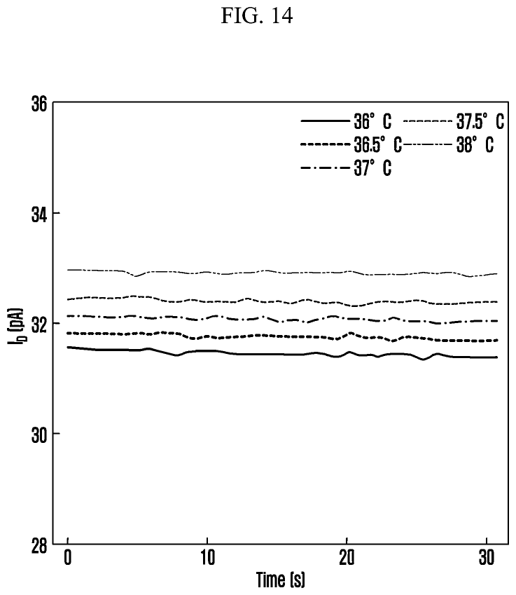

FIG. 13 is a graph showing results of evaluating NS-current and Vₜₕ change according to temperature, and FIG. 14 is a graph showing a change in crystallinity according to stretching of a green light emitting polymer semiconductor.

Referring to FIGS. 13 and 14, to verify the feasibility of using NS current as an indicator for constant temperature sensing, the change in the NS current and ΔVₜₕ over time at various temperatures was measured. Stable performance was exhibited for 30 minutes. As shown in FIG. 14, general temperature sensing resolution of the manufactured OTFT element 100 was estimated to be 0.5° C.

### <Evaluation of Transistor Component Stability According to Change in Temperature>

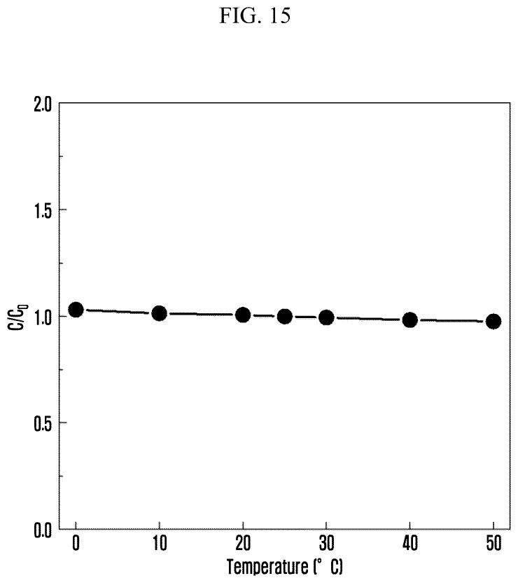

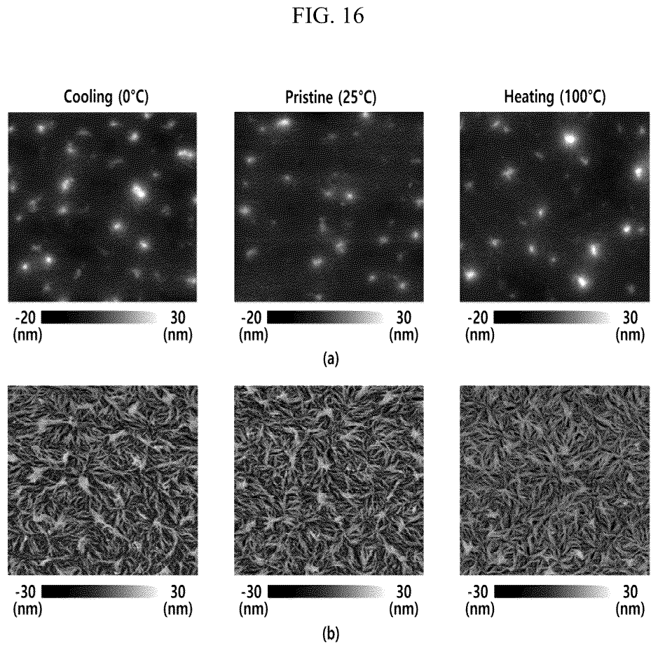

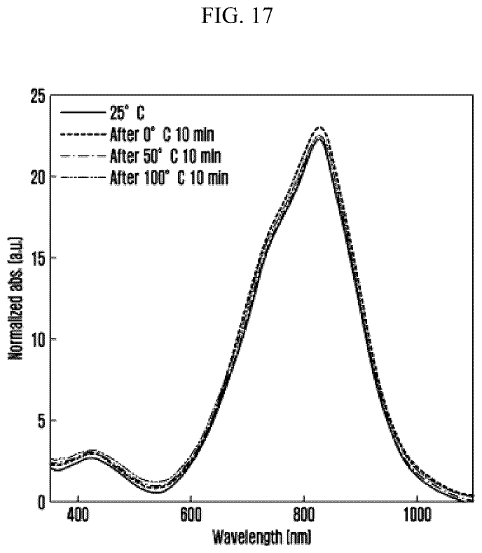

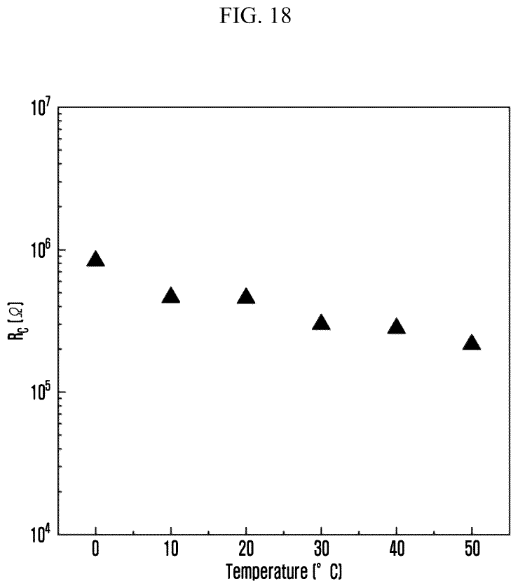

FIG. 15 is a graph showing results of evaluating a change in dielectric property according to a change in temperature, FIG. 16, (a) and (b), show results of evaluating a change in surface morphology of a semiconductor included in an active layer 60 according to a change in temperature, FIG. 17 is a graph showing results of evaluating a change in UV-vis absorption spectrum of a semiconductor film according to a change in temperature, and FIG. 18 is a graph showing results of evaluating a change in contact resistance according to a change in temperature.

Referring to FIGS. 15 to 18, the dielectric property of the dielectric layer 30 was very stable according to a change in temperature. During heating up to 100° C., surface morphology of the semiconductor film on AFM was well maintained without change. Also, the aggregation characteristic of the polymer semiconductor as seen in the UV-vis absorption spectrum, was well maintained even after heating at 100° C. for 10 minutes. The contact resistance of the OTFT element 100 was confirmed to be stable without a significant change for cooling and heating.

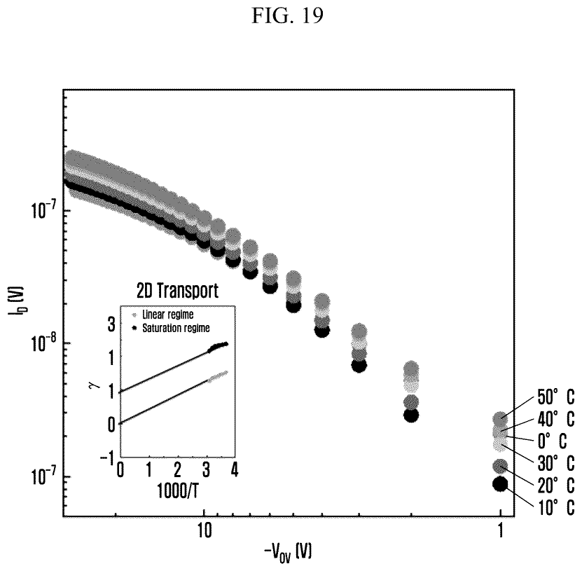

FIG. 19 is a graph showing results of evaluating a change in a transmission mode of the OTFT element 100 according to a change in temperature.

The results of FIGS. 15 to 18 show that, as shown in FIG. 19, the sub-threshold OTFT element 100 has stable charge injection and transport during a temperature holding time without encountering electrical instability related to charge trap. In particular, in terms of a transport mode, the OTFT demonstrated 2D charge carrier transport capable of reducing a length of a current path for faster charge transport compared to 3D transport.

### <Evaluation of Temperature Sensitivity of Semiconductor Film in Tensile Strain Environment>

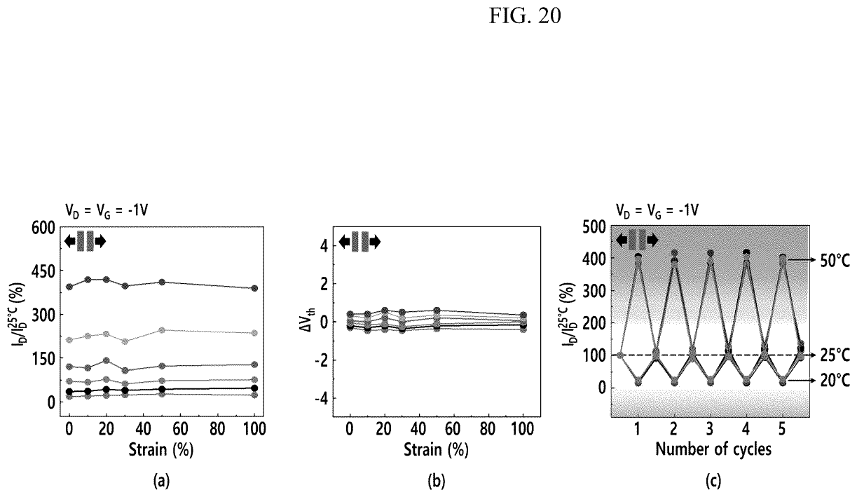

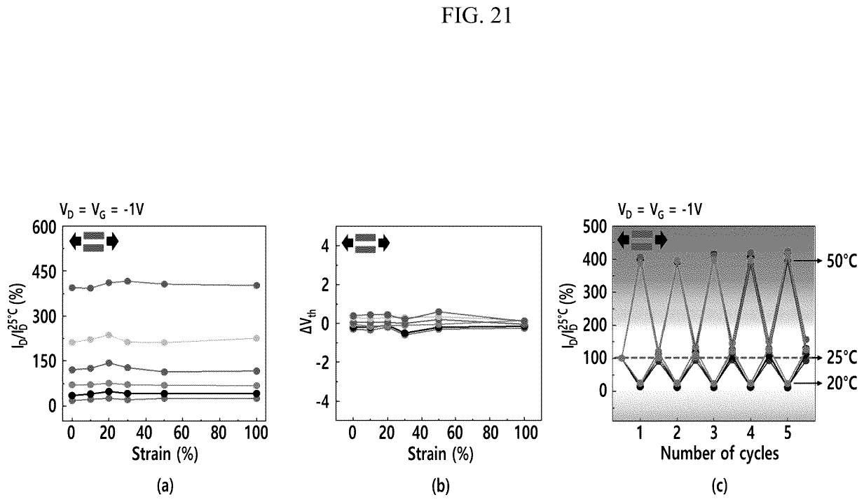

FIG. 20, (a), (b), and (c), are graphs showing results of evaluating temperature sensitivity of a semiconductor film in a tensile strain environment in a channel horizontal direction, and FIG. 21, (a), (b), and (c), are graphs showing results of evaluating temperature sensitivity of a semiconductor film in a tensile strain environment in a channel vertical direction.

Referring to FIGS. 20 and 21, to investigate the combined effect of strain and temperature for electrical property of the DPPT-TT:SEBS blend film, the OTFT array 200 was manufactured using a stretched film and then transferred to the ITO/glass substrate to exclude the effect of other components on strain. In the temperature range of 0 to 50° C. for strain directions parallel and perpendicular to a channel length, initial NS current value and temperature response were stably maintained at low ΔVₜₕ(<1V) up to 100% strain in both directions.

The results show that nanoconfined DPPT-TT nanofiber maintains an interconnected network within an elastomer matrix forming an active layer even at 100% strain, enabling efficient hopping transport due to low interfacial trap and charge scattering generated at interface between the dielectric layer and the semiconductor by strain.

ΔVₜₕ combined with interfacial trapping and charge scattering is −2.5±0.5V up to 100% strain over the entire temperature range of 0 to 50° C., which was confirmed to indicate values much smaller than those reported in the study (X. Wu, Y. Ma, G. Zhang, Y. Chu, J. Du, Y. Zhang, Z. Li, Y. Duan, Z. Fan, J. Huang, Adv. Funct. Mater. 2015, 25, 2138. etc.).

Considering these results, the reliability of the semiconductor film was additionally tested at various temperatures by repeating various cooling and heating cycles.

(c) of FIG. 20 and (c) of FIG. 21 show the change in NS current during multiple cooling cycles from 25 to 0° C. and multiple heating cycles from 20 to 50° C. for various strains. The semiconductor film exhibited the same temperature dependence of I_{D} change regardless of strain and stretching directions during several cooling and heating cycles. Such results clearly demonstrate that the NS current has a very stable temperature response without strain effect.

### <Evaluation of Electrical Performance and Temperature Response Characteristic of Stretchable Active Matrix Array Element>

Using the active layer 60 formed as the temperature responsive elastomer matrix organic semiconductor nanofiber blend film, the skin-like temperature sensor 1 in which the sub-threshold OTFT elements 100 were arranged as the 5×5 OTFT array 200 was manufactured. Here, the first electrode layer 20 including the stretchable gate electrode (G) of the OTFT array 200, which is the active matrix transistor, and the second electrode layer 70 including the source electrode (S) and the drain electrode (D) were formed on the stretchable substrate 10 and the active layer 60, respectively, through a transfer printing method using thermal evaporation Ag metallization. Then, the temperature sensor 1 was manufactured by transferring, to the active layer 60, the stretchable substrate 10 on which the first electrode layer 20 formed on the glass substrate was formed.

Through this, the manufactured temperature sensor 1 was confirmed to have the OTFT element 100 ((a) of FIG. 3) in a standardized transistor structure on the OM image and to have thin and soft characteristic ((b) of FIG. 3) enough to fit smoothly on the inside of the wrist as shown in FIG. 3.

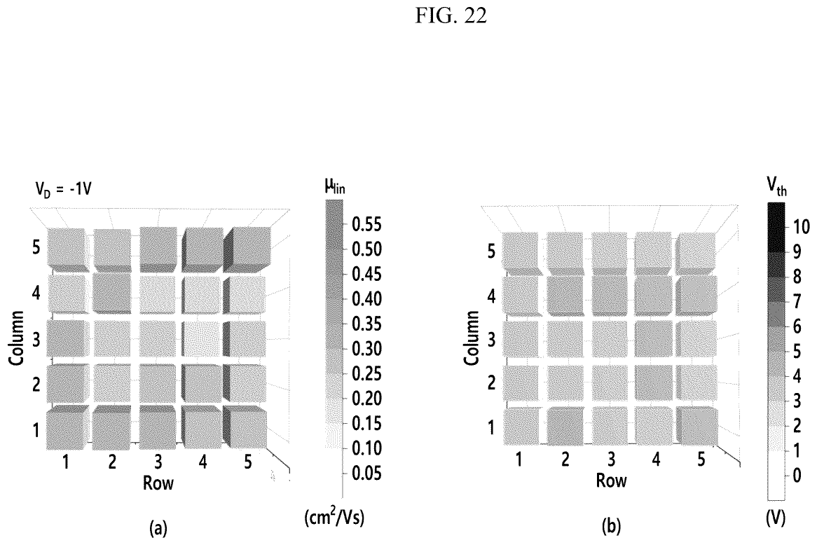

FIG. 22, (a) and (b), are graphs showing results of evaluating electrical property of 5×5 OTFT array 200.

Referring to FIG. 22, the OTFT elements 100 arranged in the temperature sensor 1 successfully operated, showing uniform field effect mobility and Vₜₕ.

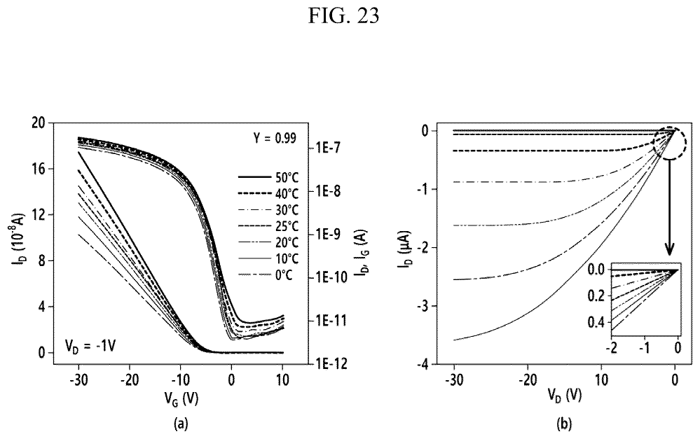

FIG. 23, (a) and (b), are graphs showing a transfer curve and an output curve in a sub-threshold region of the OTFT array 200 according to a change in temperature, respectively.

As shown in (a) of FIG. 23, the manufactured temperature sensor 1 was confirmed to have a typical transfer curve with a reliability coefficient (γ) of 0.99. This indicates that the field effect mobility of the organic transistor is not overestimated.

(b) of FIG. 23 shows the output curve of the manufactured temperature sensor 1. The output curve shown in (b) of FIG. 23 shows contact resistance of Ag metallization and I_{D} according to clearly divided V_{D} indicates that the OTFT array 200 has low contact resistance.

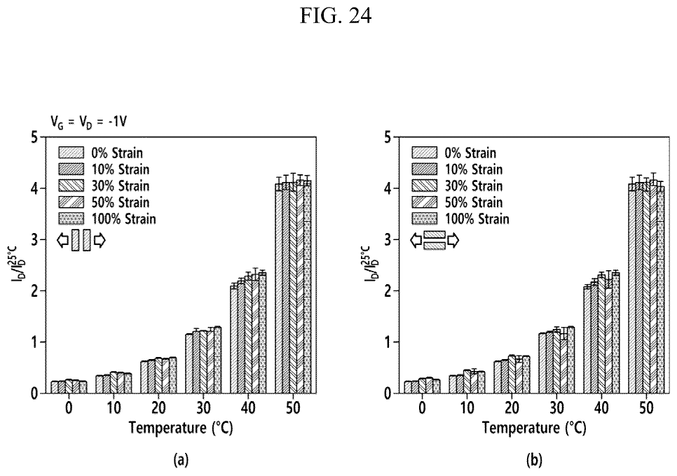

FIG. 24, (a) and (b), are graphs showing results of evaluating temperature sensitivity according to tensile strain of the OTFT array 200.

Referring to FIG. 24, in the OTFT array 200, the average NS current of the OTFT element 100 exponentially increased by temperature modulation from 0 to 50° C. according to various amplitudes and directions of applied strain. The fully stretchable sub-threshold OTFT element 100 exhibited no drop in sub-threshold current compared to a single sub-threshold OTFT element 100 on the rigid substrate. This indicates that a change in channel shape and dielectric thickness by strain hardly modulates hole transport in the sub-threshold region of the OTFT element 100. Also, temperature response is almost the same as that of the single OTFT element 100 manufactured on the rigid substrate. This indicates that the current below the threshold of the OTFT array 200 during strain is not affected by the change in the channel shape and the dielectric thickness by strain.

### <Evaluation of Temperature Sensitivity of OTFT Array 200 not Sensitive to Strain>

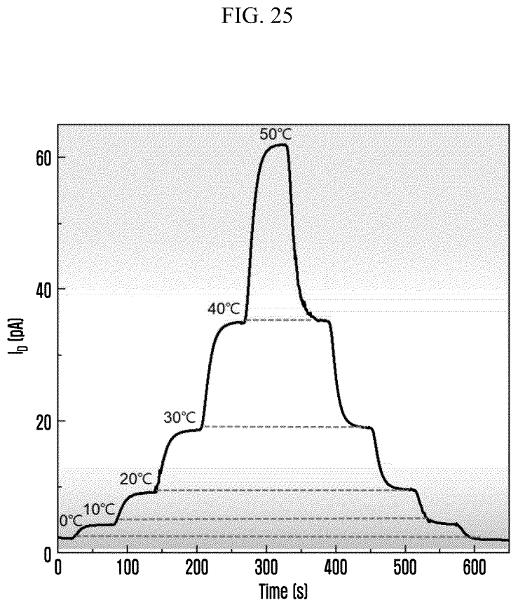

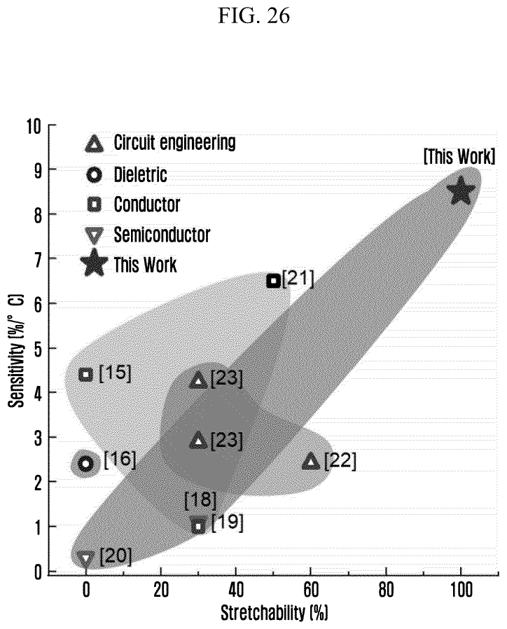

FIG. 25 is a graph showing results of evaluating a change in drain current (I_{D}) according to real-time temperature in a range similar to body temperature of the temperature sensor 1, and FIG. 26 is a graph showing comparative evaluation results of stretchability and temperature sensitivity according to a key design factor in a temperature sensor using the OTFT array 200.

FIG. 25 shows sub-threshold region current-time response curve in the sub-threshold region (V_{D}, V_{G}=−1V) of the pixel OTFT element 100 of the OTFT array 200 according to a continuous change in temperature. Referring to FIG. 25, it is confirmed that current exponentially increases and decreases depending on temperature when heating and cooling between 0 and 50° C. The sensitivity of the temperature sensor 1 was greater than or equal to 9%/° C., highest value among the conventional transistor-based stretchable temperature sensors. FIG. 26 shows comparison with the conventional arts.

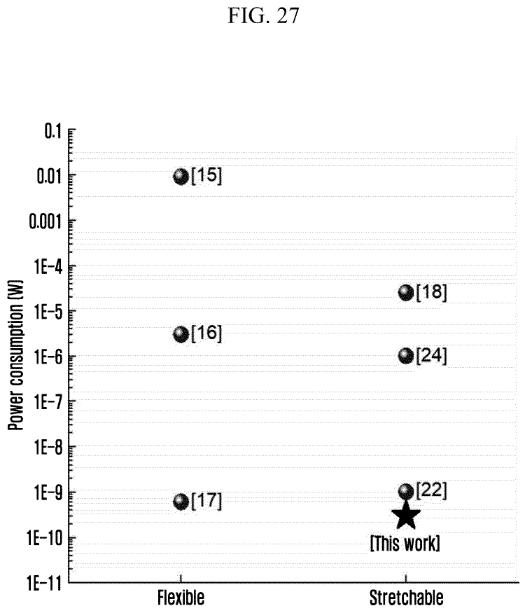

FIG. 27 is a graph showing comparative evaluation results of power consumption among flexible and stretchable transistor temperature sensor elements.

Referring to FIG. 27, considering that most organic transistors require high driving voltage, consumption power is an important parameter for wireless and safe operation, and the OTFT operating at −1 V (V_{D} and V_{G}) consumed pW-level power (up to 670 pW), lowest power consumption among previously reported power consumptions.

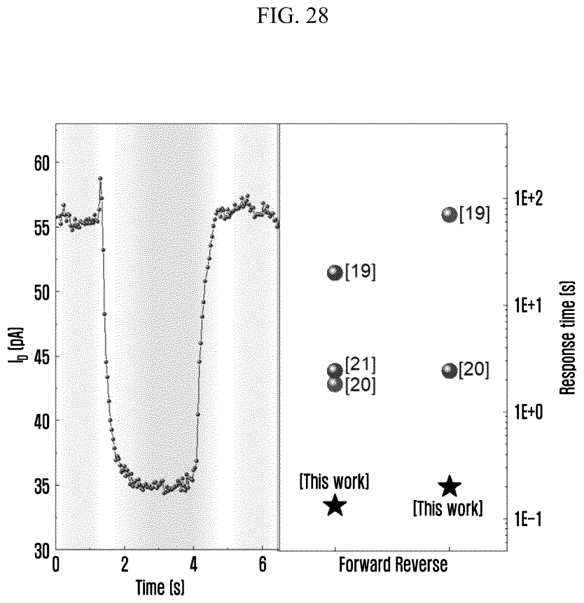

FIG. 28 is a graph showing comparative evaluation results of current response speed according to a change in reverse and forward temperature.

FIG. 28 shows results of investigating sensor response time for change in forward and reverse temperature stage of the OTFT element 100. The OTFT element 100 of the embodiment showed the response time of 300 ms, the fastest response time among flexible and stretchable transistor-based temperature sensors reported in the related art.

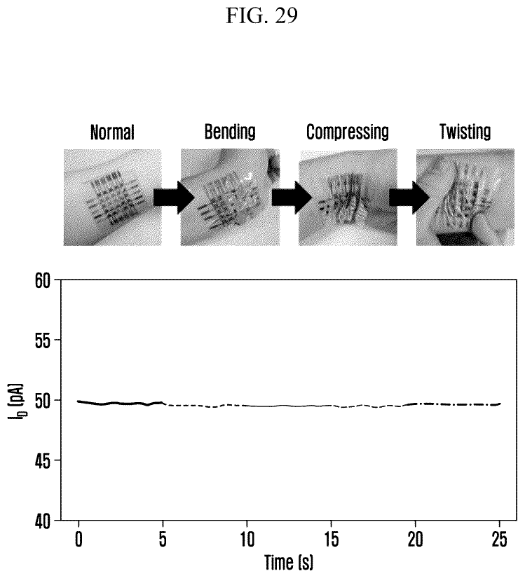

FIG. 29 is a graph showing results of evaluating current stability in various strain environments.

Referring to FIG. 29, it was confirmed that, in the current time response curve according to movement of the temperature sensor 1 mounted on the inside of the wrist of a person, the temperature sensor 1 showed consistent response despite sequential bending, compressing, and twisting. As a result, it was confirmed that a change in a shape of the temperature sensor 1 did not affect temperature measurement.

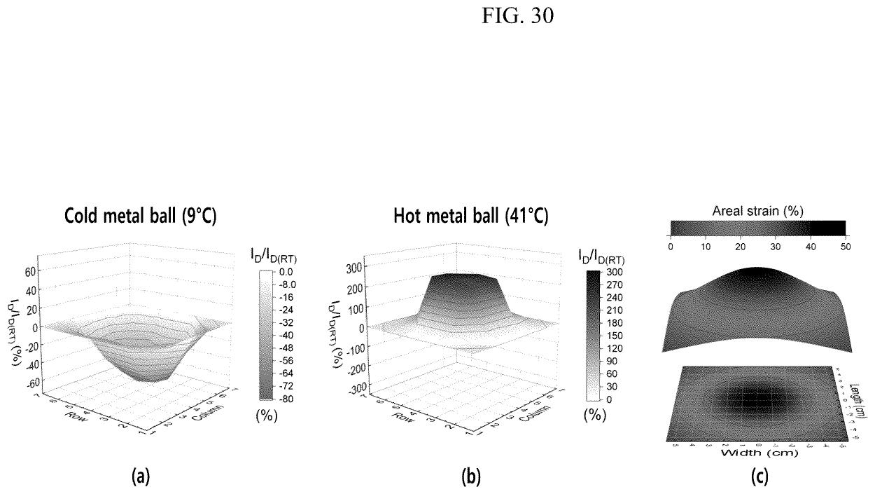

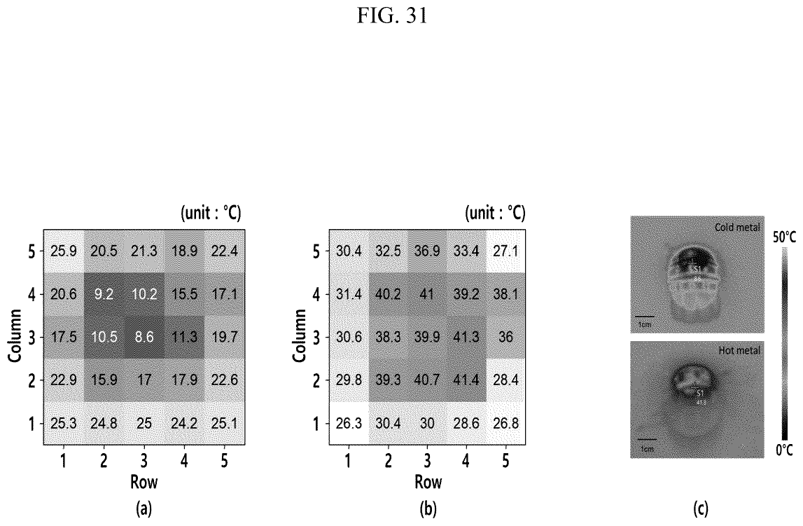

FIG. 30, (a), (b), and (c), are graphs showing NS-current and deformed 3D mapping using a cold or hot metal ball, and FIG. 31, (a), (b), and (c), are graphs showing results of evaluating temperature sensing accuracy using NS-current changed due to a cold or hot metal ball.

Referring to FIGS. 30 and 31, each sub-threshold current of the temperature sensor 1 deformed by metal ball indentation was converted to a temperature value with accuracy of 94.9% at 25° C. Accordingly, surface temperature mapping was successfully performed. There was no decrease in sensitivity of the temperature sensor 1 due to strain of up to 45% during 3D strain at room temperature. The NS current mapping results of the temperature sensor 1 present under each cold metal ball press showed converted temperature distribution from the same NS current mapping as thermal imaging scanning results.

According to example embodiments, it is possible to easily manufacture a skin attachable temperature sensor, which is a stretchable sub-threshold active matrix array temperature sensor, through a stretchable substrate, a dielectric layer, a first electrode layer, an active layer that is an organic semiconductor nanofiber elastomer blend film layer, and a second electrode layer.

According to example embodiments, it is possible to easily provide a next-generation stretchable skin-like temperature sensor with improved characteristic, such as high temperature sensitivity, low power consumption, and fast response time compared to the conventional art.

According to example embodiments, an intrinsically stretchable organic sub-threshold transistor that operates at low voltage (−1V) is presented, which may provide a skin attachable temperature sensor having very high sensitivity while having ultra-low power consumption (<1 nW) characteristic.

According to example embodiments, it is possible to provide a skin attachable temperature sensor with high temperature sensitivity (9.4% ° C.−1) and excellent sensing stability up to 100% strain by highly-temperature dependent hopping transport of a fully stretchable sub-threshold transistor.

Effects of the invention are not limited to the aforementioned effect and other effect not described herein may be clearly understood by one of ordinary skill in the art from the description.

While the present invention is described with reference to specific example embodiments, it will be apparent to one of ordinary skill in the art that various changes and modifications in forms and details may be made in these example embodiments without departing from the technical spirit of the various example embodiments.

Therefore, other implementations, other example embodiments, and equivalents of the claims are to be construed as being included in the claims.

What is claimed is:

1. A stretchable organic thin film field effect transistor (OTFT) element comprising:
a gate electrode;
a dielectric layer stacked with elastomer on the gate electrode;
an active layer stacked on the dielectric layer; and
a source electrode and a drain electrode formed to be spaced part from each other on the active layer,
wherein the active layer is formed as an elastomer matrix organic semiconductor nanofiber blend film in which organic semiconductor nanofiber is mixed within an elastomer matrix.

2. The stretchable OTFT element of claim 1, wherein an organic semiconductor that forms the organic semiconductor nanofiber is DPPT-TT that is represented by Formula 1 below.

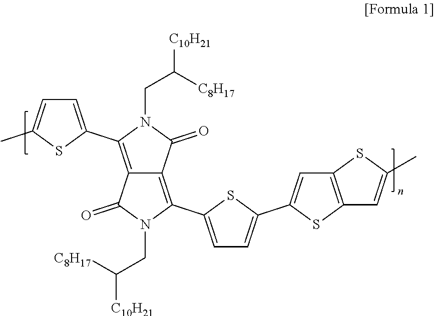

3. The stretchable OTFT element of claim 1, wherein the elastomer is styrene-ethylene-butylene-styrene (SEBS) organic elastomer that is represented by Formula 2 below.

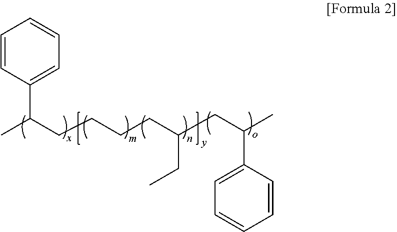

4. The stretchable OTFT element of claim 3, wherein the SEBS has a composition ratio of 18:82 to 20:80 for (x+o) to (m+n).

5. The stretchable OTFT element of claim 1, wherein the elastomer matrix organic semiconductor nanofiber blend film is manufactured by dissolving DPPT-TT represented by Formula 1 below and SEBS represented by Formula 2 below in a material of Formula 3 below at a concentration of 0.6 to 0.8% by weight at a weight ratio of 1 to 3:7 to 9.

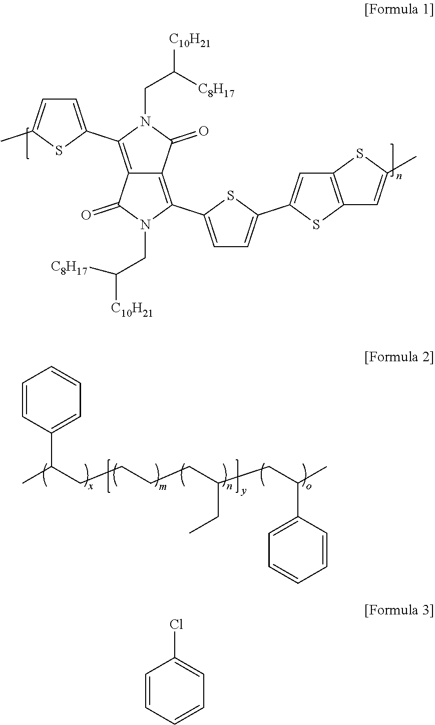

6. The stretchable OTFT element of claim 1, further comprising:
a substrate on which the gate electrode is formed,
wherein the substrate is manufactured by mixing a material of Formula 2 below with a material of Formula 4 below at a centration of 90 to 110 mg/mL and then performing spin coating on a rigid substrate.

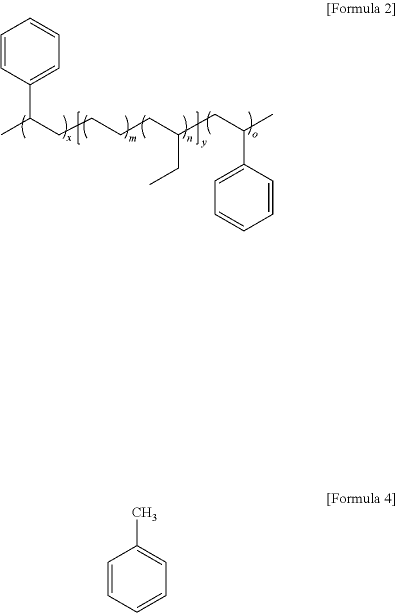

7. The stretchable OTFT element of claim 1, wherein the dielectric layer is a SEBS matrix manufactured by mixing a material of Formula 2 below with a material of Formula 4 below at a concentration of 50 to 70 mg/mL and then performing spin coating on a rigid substrate.

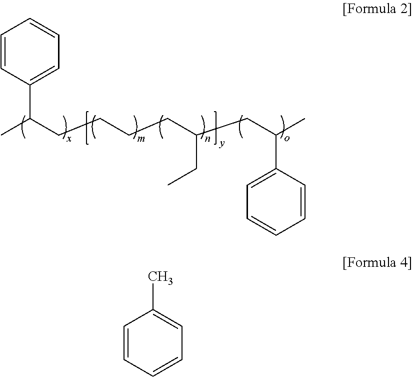

8. The stretchable OTFT element of claim 1, further comprising:
a substrate on which the gate electrode is formed,
wherein the gate electrode and the source electrode and the drain electrode are formed on the substrate and the active layer, respectively, by a transfer printing method that uses metallization of a thermally evaporated metal conductor.

9. A skin attachable temperature sensor comprising:
a substrate formed of elastomer;
a first electrode layer formed on the substrate by including at least one gate electrode;
a dielectric layer stacked with the elastomer on the substrate and the first electrode layer;
an active layer stacked on the dielectric layer;
a second electrode layer stacked on the active layer by including at least one source electrode and drain electrode; and
a capsule layer configured to seal the top of the second electrode layer,
wherein the active layer is formed as an elastomer matrix organic semiconductor nanofiber blend film in which organic semiconductor nanofiber is mixed within an elastomer matrix.

10. The skin attachable temperature sensor of claim 9, wherein an organic semiconductor that forms the organic semiconductor nanofiber is DPPT-TT that is represented by Formula 1 below.

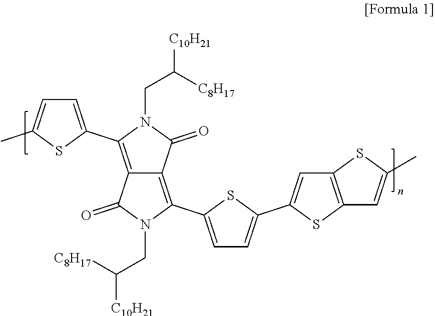

11. The skin attachable temperature sensor of claim 9, the elastomer is styrene-ethylene-butylene-styrene (SEBS) organic elastomer that is represented by Formula 2 below.

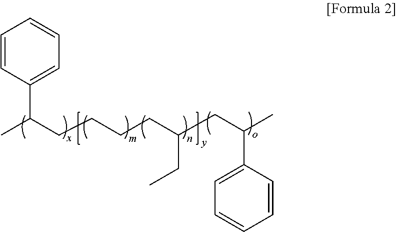

12. The skin attachable temperature sensor of claim 11, wherein the SEBS has a composition ratio of 18:82 to 20:80 for (x+o) to (m+n).

13. The skin attachable temperature sensor of claim 9, wherein the elastomer matrix organic semiconductor nanofiber blend film is manufactured by dissolving DPPT-TT represented by Formula 1 below and SEBS represented by Formula 2 in a material of Formula 3 below at a concentration of 0.6 to 0.8% by weight at a weight ratio of 1 to 3:7 to 9.

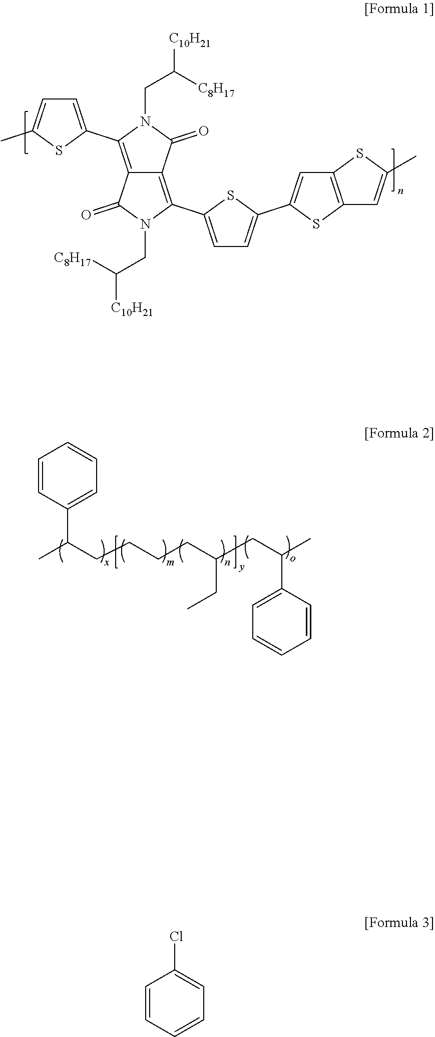

14. The skin attachable temperature sensor of claim 9, wherein the substrate is manufactured by mixing a material of Formula 2 below with a material of Formula 4 below at a centration of 90 to 110 mg/mL and then performing spin coating on a rigid substrate.

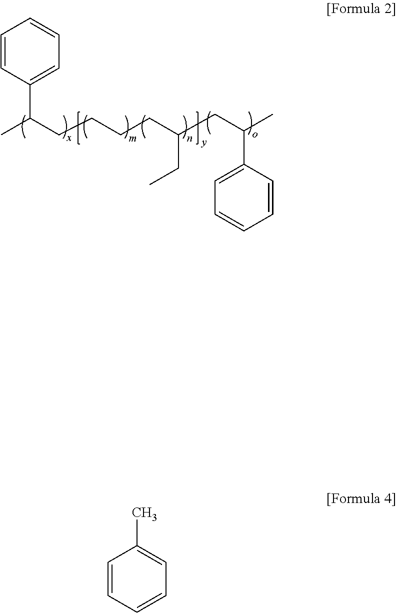

15. The skin attachable temperature sensor of claim 9, wherein the dielectric layer is a SEBS matrix manufactured by mixing a material of Formula 2 below with a material of Formula 4 below at a concentration of 50 to 70 mg/mL and then performing spin coating on a rigid substrate.

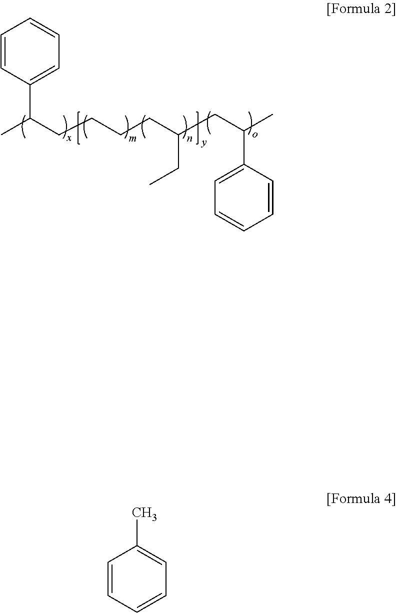

16. The skin attachable temperature sensor of claim 9, wherein the first electrode layer and the second electrode layer are formed on the substrate and the active layer, respectively, by a transfer printing method that uses metallization of a thermally evaporated metal conductor.

17. A method of manufacturing a skin attachable temperature sensor, the method comprising:
a substrate, dielectric layer, and active layer manufacturing operation of simultaneously or sequentially manufacturing a substrate, a dielectric layer, and an active layer on each of separated wafers or glass substrates;
a first electrode layer forming operation of forming stretchable at least one gate electrode on the substrate through thermal evaporation under vacuum using a patterning mask;
a second electrode layer forming operation of forming at least one source electrode and drain electrode on the active layer; and
a dielectric layer and active layer transferring operation of transferring the dielectric layer on the substrate on which the first electrode layer is formed and transferring the active layer on the dielectric layer such that the second electrode layer is present on the top,
wherein, in the substrate, dielectric layer, and active layer manufacturing operation, the active layer is manufactured by mixing organic semiconductor nanofiber of Formula 1 below and elastomer of Formula 2 below in a solvent that contains a material of Formula 3 below.

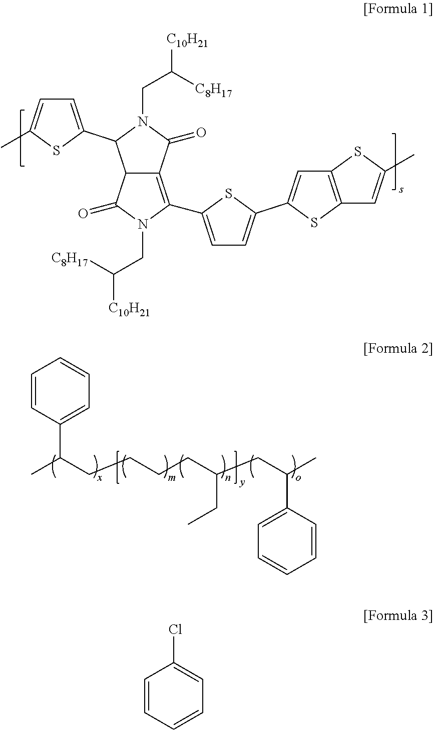

18. The method of claim 17, wherein, in the substrate, dielectric layer, and active layer manufacturing operation, the substrate is manufactured as a stretchable substrate by mixing the material of Formula 2 above with a material of Formula 4 below at a concentration of 90 to 110 mg/mL and then performing spin coating on a rigid substrate.

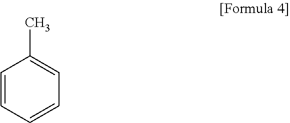

19. The method of claim 17, wherein, in the substrate, dielectric layer, and active layer manufacturing operation, the dielectric layer is formed as a SEBS matrix by mixing the material of Formula 2 above with a material of Formula 4 below at a concentration of 50 to 70 mg/mL and then performing spin coating on a rigid substrate.

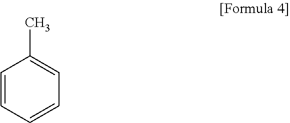

20. The method of claim 17, wherein, in the substrate, dielectric layer, and active layer manufacturing operation, the active layer is manufactured as a DPPT-TT: SEBS blend film in which an organic semiconductor nanofiber film is formed as the active layer by dissolving DPPT-TT represented by Formula 1 above and SEBS represented by Formula 2 above with the material of Formula 3 above at a concentration of 0.6 to 0.8% by weight at a weight ratio of 1 to 3:7 to 9 for the total weight on a rigid substrate and then generating a filtration solution and by spin-coating and then annealing the filtration solution.
